(19) United States
(12) Patent Application Publication
(10) Pub. No.: US 2023/0132102 A1
(43) Pub. Date: Apr. 27, 2023

(54) METHOD FOR ESTIMATING STATE OF HEALTH (SOH) OF BATTERY

(71) Applicant: SK ON CO., LTD., Seoul (KR)

(72) Inventors: Ye Kyu KIM, Daejeon (KR); Byung Eun LEE, Daejeon (KR); Hyung Keun LEE, Daejeon (KR)

(21) Appl. No.: 17/971,417

(22) Filed: Oct. 21, 2022

(30) Foreign Application Priority Data
Oct. 21, 2021 (KR) 10-2021-0141134

(51) Int. Cl. G01R 31/392; G01R 31/367; G01R 31/3835

(52) U.S. Cl. CPC G01R 31/392; G01R 31/367; G01R 31/3835

(57) ABSTRACT

A method for estimating a state of health (SOH) of a battery includes obtaining a state of charge (SOC)-open circuit voltage (OCV) lookup table according to a SOH of a battery module or battery pack, and storing the SOC-OCV lookup table in a memory, calculating, based on a diagnosis time and a current rate, a first SOC change amount when the diagnosis time and the current rate are input, calculating a first slope for each SOC section corresponding to the first SOC change amount according to the SOH in the SOC-OCV lookup table according to the SOH, and determining, based on the first slope, first sections having high diagnostic accuracy.

### CROSS-REFERENCE TO RELATED APPLICATION(S)

This application claims benefit of priority to Korean Patent Application No. 10-2021-0141134 filed on Oct. 21, 2021 in the Korean Intellectual Property Office, the disclosure of which is incorporated herein by reference in its entirety.

### TECHNICAL FIELD

The present disclosure relates to a method for estimating a state of health (SOH) of a battery.

### BACKGROUND

The state of health (SOH) of a battery is an important parameter in battery operations. A state of health (SOH) of a battery may be estimated through a short-section discharge process by conducting a diagnosis method using a state of charge (SOC)-open circuit voltage (OCV) lookup table of a beginning of life (BOL) battery. BOL refers to a point in time at which a lifespan of a battery begins.

At the time of battery development, the SOC-OCV lookup table of the BOL battery is pre-stored in a storage device. A current SOH of the battery is determined using the SOC-OCV lookup table stored in the storage device. However, when the battery is degraded, an OCV in the SOC-OCV lookup table may be changed. Therefore, when the battery is degraded, it is difficult to accurately determine the current SOH of the battery using the SOC-OCV lookup table. In addition, it is necessary to devise a method for accurately determining a SOH so as to determine whether to recycle a battery that is degraded to a certain degree.

### SUMMARY

An aspect of the present disclosure provides a method for estimating a state of health (SOH) of a battery in which a section having high diagnostic accuracy is predetermined through slope analysis in a state of charge (SOC)-open circuit voltage (OCV) lookup table according to the SOH, and the SOH of the battery is estimated in the section.

According to an aspect of the present disclosure, provided is a method for estimating a SOH of a battery, the method including obtaining an SOC-OCV lookup table according to a SOH-of a battery module or battery pack, and storing the SOC-OCV lookup table in a memory, calculating, based on a diagnosis time and a current rate, a first SOC change amount when the diagnosis time and the current rate are input, calculating a first slope for each SOC section corresponding to the first SOC change amount according to the SOH in the SOC-OCV lookup table according to the SOH, and determining, based on the first slope, first sections having high diagnostic accuracy.

According to example embodiments of the present disclosure, in a method for estimating a SOH of a battery, the method may predetermine a section having high diagnostic accuracy through slope analysis in an SOC-OCV lookup table according to a SOH of at least one battery cell, and may estimate the SOH of the battery in the section, thereby quickly and accurately determining the SOH of the battery.

In addition, when a battery of a vehicle has reached the end of a lifespan thereof or the vehicle is scrapped, the method may serve as a criterion for determining whether to discard or reuse the battery after use.

In addition, a current state of a degraded battery may be diagnosed through the method.

Various and beneficial advantages and effects of the present disclosure are not limited to the above description, and will be more easily understood in the course of describing specific example embodiments of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a state of charge (SOC)-open circuit voltage (OCV) graph illustrating a general state of health (SOH) estimation method;

FIG. 2 is a schematic block diagram illustrating an apparatus for estimating a SOH of a battery according to an example embodiment of the present disclosure;

FIG. 3 is a flowchart of a first process illustrating a method for estimating a SOH of a battery according to an example embodiment of the present disclosure;

FIG. 4 is a diagram illustrating a method for calculating a slope according to an example embodiment of the present disclosure;

FIG. 5 is a diagram illustrating a method for determining a section having high diagnostic accuracy according to an example embodiment of the present disclosure;

FIG. 6 is a schematic block diagram illustrating an apparatus for estimating a SOH of a battery according to an example embodiment of the present disclosure;

FIGS. 7 and 8 are flowcharts of a second process illustrating a method for estimating a SOH of a battery according to an example embodiment of the present disclosure; and

FIG. 9 is a schematic block diagram illustrating an apparatus for estimating a SOH of a battery according to an example embodiment of the present disclosure.

### DETAILED DESCRIPTION

The details of other example embodiments are included in the detailed description and drawings.

The aspects and features of the present disclosure and methods of achieving the aspects and features will be apparent by referring to the example embodiments to be described in detail with reference to the accompanying drawings. However, the present disclosure is not limited to the example embodiments disclosed hereinafter, but can be implemented in various different forms. The example embodiments are merely provided so that the present disclosure is thorough and complete, and fully conveys the scope of the present disclosure to those skilled in the art, and the present disclosure is only defined within the scope of the appended claims. Throughout the entire specification, the same or like reference numerals designate the same or like elements.

Terms such as “ . . . unit,” “ . . . module,” and the like used below may refer to units for processing at least one function or operation, and may be implemented in hardware, software, or a combination of hardware and software.

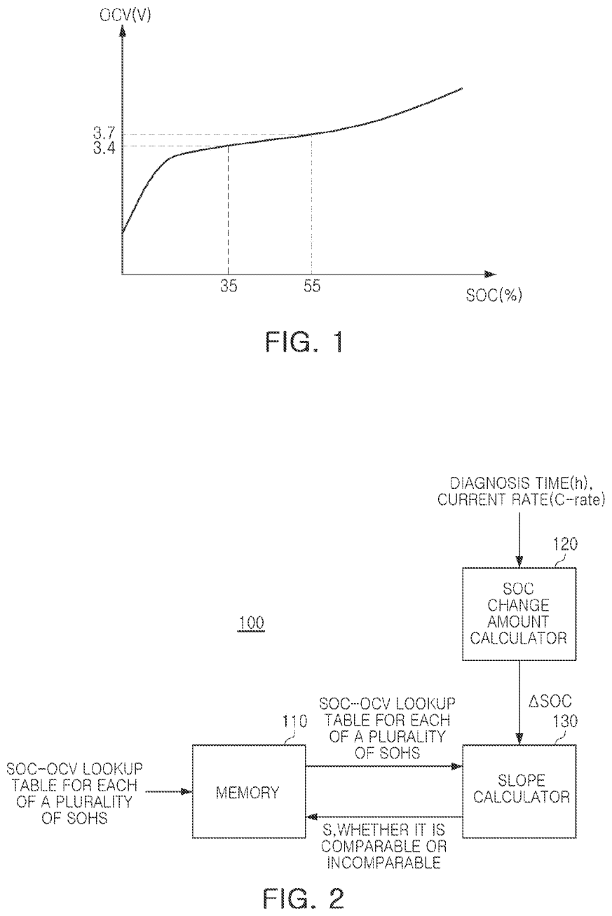

FIG. 1 is a state of charge (SOC)-open circuit voltage (OCV) graph illustrating a general state of health (SOH) estimation method. In some implementations, the state of charge (SOC) may indicate the level of charge of a battery relative to its capacity. In some implementations, the open circuit voltage (OCV) may indicate a voltage difference between positive and negative terminals of a battery without any load connected.

A charger/discharger may be electrically connected to a battery, and the battery may be charged and discharged by the charger/discharger. A discharge capacity (Ah) may be measured when the battery is discharged through the charger/discharger. A method for calculating an SOH using the SOC-OCV graph may be as follows.

For example, the discharge capacity measured by discharging the battery for one hour may be 10 (Ah), and an OCV may be changed from 3.7 V to 3.4 V. When an OCV change amount is identified in the graph of FIG. 1, an SOC change amount (A SOC) may be identified. In the graph of FIG. 1, when the OCV is changed from 3.7 V to 3.4 V, ΔSOC may be 20(%). ΔSOC that is 20(%) may mean that the measured discharge capacity of 10 (Ah) is a capacity in which only 20% of a total capacity is discharged. Thus, the total capacity may be 50 (Ah). A SOH may be calculated by dividing the total capacity by a BOL capacity, which may be represented by Equation 1.

$$SOH [ \% ] = \frac{Measured Capacity [ Ah ]}{Δ SOC ⨯ BOL capacity [ Ah ]} ⨯ 100 \qquad ( Equation 1 )$$

Here, the BOL capacity may refer to a battery capacity during shipment, that is, an earliest battery capacity.

The general SOH estimation method may be performed by determining an SOC change amount (ΔSOC) based on an OCV change amount, and calculating a SOH through ΔSOC. When a battery is degraded, a slope of the SOC-OCV graph illustrated in FIG. 1 may be changed. Accordingly, when the battery is degraded, it may be difficult to accurately determine a current SOH of the battery using the SOC-OCV graph.

According to an example embodiment of the present disclosure, a section having high diagnostic accuracy may be predetermined through slope analysis in an SOC-OCV lookup table according to a SOH that a battery cell may have, and the SOH of the battery cell may be estimated in the section. Accordingly, in a degraded battery, a SOH estimation error of a battery cell may be reduced, and a SOH of the battery cell may be quickly and accurately determined.

A method for estimating a SOH of a battery according to an example embodiment of the present disclosure, the method may include a first process of determining a section having high diagnostic accuracy through slope analysis in an SOC-OCV lookup table according to a SOH that a battery cell may have, and a second process of diagnosing a SOH of a waste battery when the waste battery is stocked.

However, the method may be applicable to a battery module, battery pack, battery system, or the like, including a plurality of battery cells as well as a single battery cell. In applying the method to the battery module, battery pack, battery system, or the like including the plurality of battery cells, an average of an SOC-OCV lookup table for the plurality of battery cells may be used. Accordingly, a SOI obtained as a result of the method for the battery module, battery pack, battery system, or the like may be a value obtained by estimating an average SOH of the plurality of battery cells included in the battery module, battery pack, battery system, or the like.

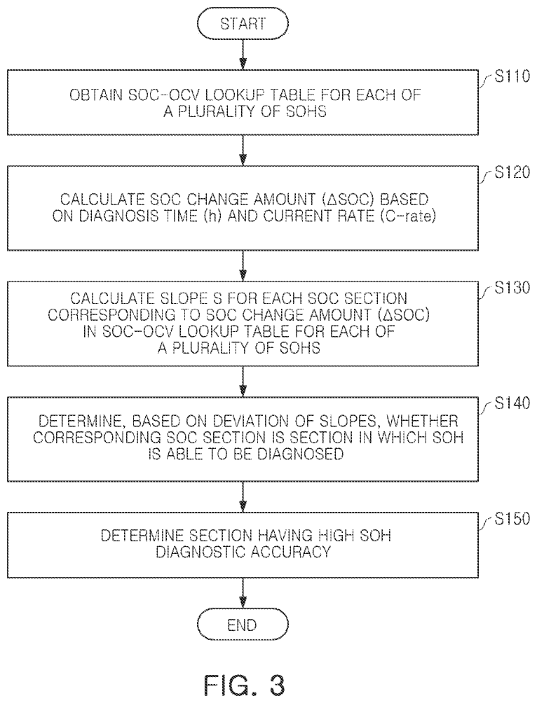

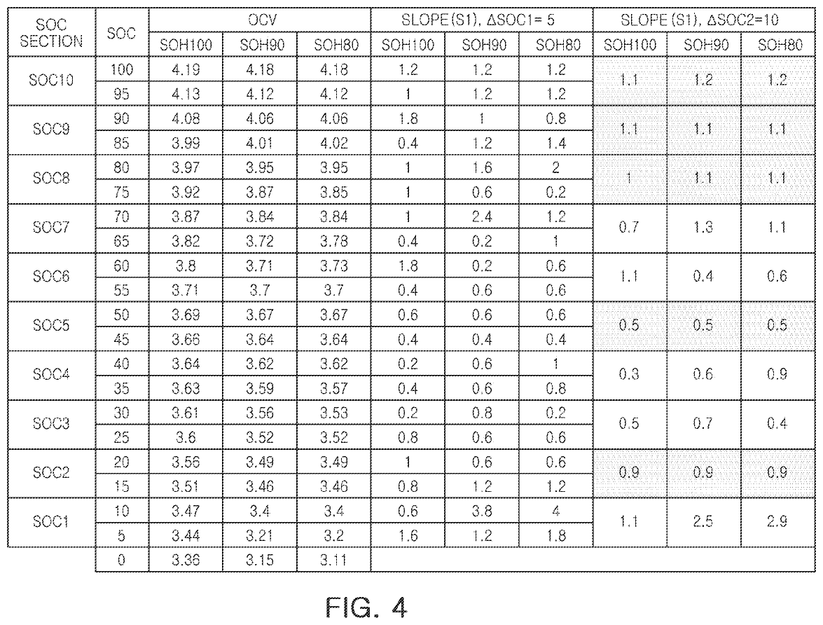

FIG. 2 is a schematic block diagram illustrating an apparatus for estimating a SOH of a battery according to an example embodiment of the present disclosure. FIG. 3 is a flowchart of a first process illustrating a method for estimating a SOH of a battery according to an example embodiment of the present disclosure.

Referring to FIG. 2, an apparatus 100 for estimating a SOH of a battery, the apparatus 100 may include a memory 110, an SOC change amount calculator 120, and a slope calculator 130. The apparatus 100 may predetermine a section having high diagnostic accuracy through slope analysis in an SOC-OCV lookup table according to a SOH that a battery module or battery pack may have, and may recommend the section when the SOH of the battery is estimated.

Referring to FIGS. 2 and 3 together, at the time of battery development, the apparatus 100 may obtain an SOC-OCV lookup table according to a SOH that at least one battery cell may have (S110). For example, the apparatus 100 may include an SOC-OCV lookup table of a battery cell having a SOH of 100, a SOC-OCV lookup table of a battery cell having a SOH of 90, and a SOC-OCV lookup table of a battery cell having a SOH of 80, respectively. In this case, the SOH may be a value actually measured through a battery cell charger/discharger. The SOC-OCV lookup table according to the SOH may be stored in the memory 110.

When a diagnosis time (h) and a current rate (C-rate) are input to the apparatus 100, the SOC change amount calculator 120 may calculate an SOC change amount (ΔSOC) corresponding to the diagnosis time (h) and the current rate (C-rate) (S120). The diagnosis time (h) may refer to a time required for diagnosing a current state of the battery, and a diagnosis time desired by a user may be input into the apparatus 100. The current rate (C-rate) may vary depending on a degree of the battery being degraded. For example, as the battery is degraded, the current rate (C-rate) may have a lower value. In some implementations, the current rate (C-rate) may indicate a rate at which a battery is discharged relative to its maximum capacity. In some implementations, the current rate (C-rate) may indicate the time it takes to charge or discharge the battery. For example, an IC rate means that the discharge current will discharge the entire battery in 1 hour.

The SOC change amount (ΔSOC) may satisfy Equation 2.

$$Δ SOH [ \% ] = \frac{Diagnosis Time [ h ]}{Current Rate ( C - rate ) [ h ]} ⨯ 100 \qquad ( Equation 2 )$$

For example, when the input diagnosis time (h) is six minutes (=0.1 hours) and the input current rate (C-rate) is 1 C, the SOC change amount (ΔSOC) may be 10%.

The slope calculator 130 may read, from the memory 110, the SOC-OCV lookup table according to the SOH that the battery cell may have, and calculate a slope S for each SOC section corresponding to the SOC change amount (ΔSOC) in the SOC-OCV lookup table according to the SOH that the battery cell may have. (S130).

The slope S may satisfy Equation 3.

$$S = \frac{O C V 2 - OCV 1}{Δ SOC} \qquad ( Equation 3 )$$

In [Equation 3] above, an OCV change amount (OCV2-OCV1) corresponding to the SOC change amount (ΔSOC) may be calculated, and the slope S may be calculated by dividing the OCV change amount (OCV2-OCV1) by the SOC change amount (ΔSOC).

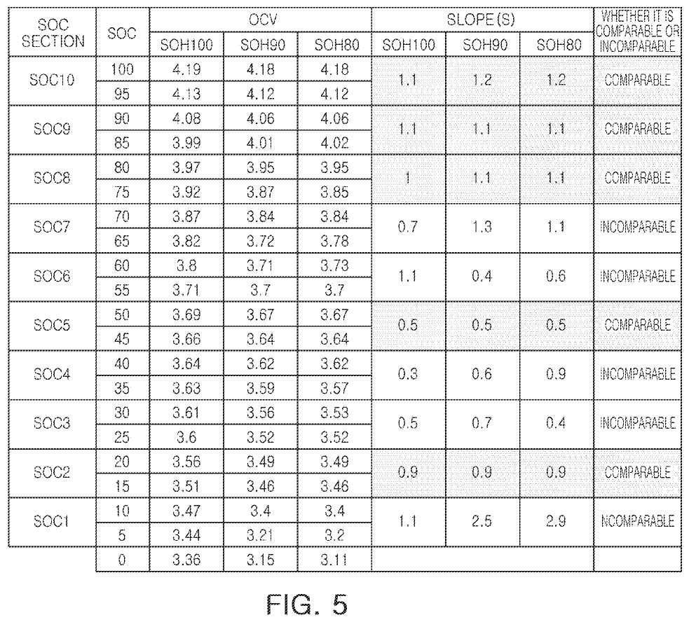

FIG. 4 is a diagram illustrating a method for calculating a slope according to an example embodiment of the present disclosure.

Referring to FIGS. 2 and 4 together, the slope calculator 130 may calculate a first slope S1 for each SOC section corresponding to a first SOC change amount (ΔSOC1=5) in the SOC-OCV lookup table according to the SOH that the battery cell may have. For example, when a first OCV is 3.36 V and a second OCV is 3.44 in an SOC-OCV lookup table of a battery having a SOH of 100, the first slope S1 may be calculated as follows.

$$S 1 = \frac{3.44 - 3.36}{5} ⨯ 100 = 1.6$$

When the first OCV is 3.44 V and the second OCV is 3.47 in the SOC-OCV lookup table of the battery having the SOH of 100, the first slope S1 may be calculated as follows.

$$S 1 = \frac{3.47 - 3.44}{5} ⨯ 100 = 0.6$$

The slope calculator 130 may calculate a second slope S2 for each SOC section corresponding to a second SOC change amount (ΔSOC2=10). The slope calculator 130 may calculate the second slope S2 based on the first slope S1. The second slope S2 may be an average value of two adjacent first slopes S1. For example, in the SOC-OCV lookup table of the battery having the SOH of 100, a second slope S2 of a first section SOC1 may be calculated as follows.

$$S 2 = \frac{0.6 + 1.6}{2} = 1.1$$

In some example embodiments, the apparatus 100 may calculate the second slope S2 directly without calculating the first slope SL For example, when the first OCV is 3.36 V and the second OCV is 3.47 in the SOC-OCV lookup table of the battery having the SOH of 100, the second slope S2 may be calculated as follows.

$$S 2 = \frac{3.47 - 3.36}{10} ⨯ 100 = 1.1$$

Referring back to FIGS. 2 and 3 together, the slope calculator 130 may determine whether each SOC section corresponding to the SOC change amount (ΔSOC=10) is a section in which a. SOH is able to be diagnosed. The slope calculator 130 may determine, based on a deviation of slopes of a plurality of SOHs in the same SOC section, whether a corresponding SOC section is a section in which a SOH is able to be diagnosed. When it is determined that the SOC section is a section in which a SOH is able to be diagnosed, the slope calculator 130 may output the SOC section as a comparable section. When it is determined that the SOC section is a section in which a SOH is not able to be diagnosed, the slope calculator 130 may output the SOC section as an incomparable section. The apparatus 100 may determine a comparable SOC section as a section having high diagnostic accuracy.

The apparatus 100 may determine a section having highest diagnosis accuracy (S150). For example, the slope calculator 130 may sort and output SOC sections in an order in which a deviation of slopes is small among comparable sections. The apparatus 100 may determine an SOC section having a smallest deviation of the slopes as a section having highest diagnosis accuracy.

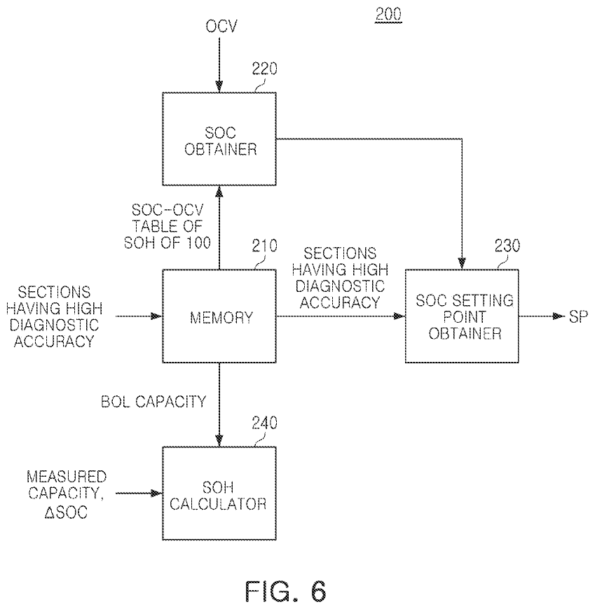

FIG. 5 is a diagram illustrating a method for determining a section having high diagnostic accuracy according to an example embodiment of the present disclosure.

Referring to FIGS. 2 and 5 together, the slope calculator 130 may calculate a slope S for each SOC section corresponding to an SOC change amount (ΔSOC=10), and may store the slope S in the memory 110.

The slope calculator 130 may determine a comparable section when a deviation of slopes according to a SOH that a battery cell may have in the same SOC section is within a predetermined range. For example, in a first SOC section SOC1, a slope S of a battery having a SOH of 100 may be 1.1, a slope S of a battery having a SOH of 90 may be 2.5, and a slope S of a battery having a SOH of 80 may be 2.9. A deviation of slopes of a plurality of SOHs in the first SOC section SOC1 may be 10% or more, the slope calculator 130 may determine the first SOC section SOC1 as an incomparable section.

In a second SOC section SOC2, a slope of S battery having a SOH of 100 may be 0.9, a slope S of a battery having a SOH of 90 may be 0.9, and a slope S of a battery having a SOH of 80 may be 0.9. A deviation of slopes of a plurality of SOHs in the second SOC section SOC2 may be less than 10%, the slope calculator 130 may determine the second SOC section SOC2 as a comparable section.

The slope calculator 130 may store, in the memory 110, sections SOC2, SOC5, SOC8, SOC9, and SOC10 in which a deviations of slope is within a predetermined range as comparable sections. The sections SOC2, SOC5, SOC8, SOC9, and SOC10 may be referred to as sections having high diagnostic accuracy.

In some example embodiments, the slope calculator 130 may sort and output SOC sections in an order in which a deviation of slopes is small among the comparable sections. For example, a deviation of slopes may be the same in the sections SOC2, SOC5, and SOC9 of a first group, and a deviation of slopes may be the same in the sections SOC8 and SOC10 of a second group. The deviation of the slopes in the sections SOC2, SOC5, and SOC9 of the first group may be smaller than the deviation of the slopes in the sections SOC8 and SOC10 of the second group. Accordingly, the apparatus 100 may determine the sections SOC2, SOC5, and SOC9 of the first group having a small deviation of slopes as sections having highest diagnosis accuracy.

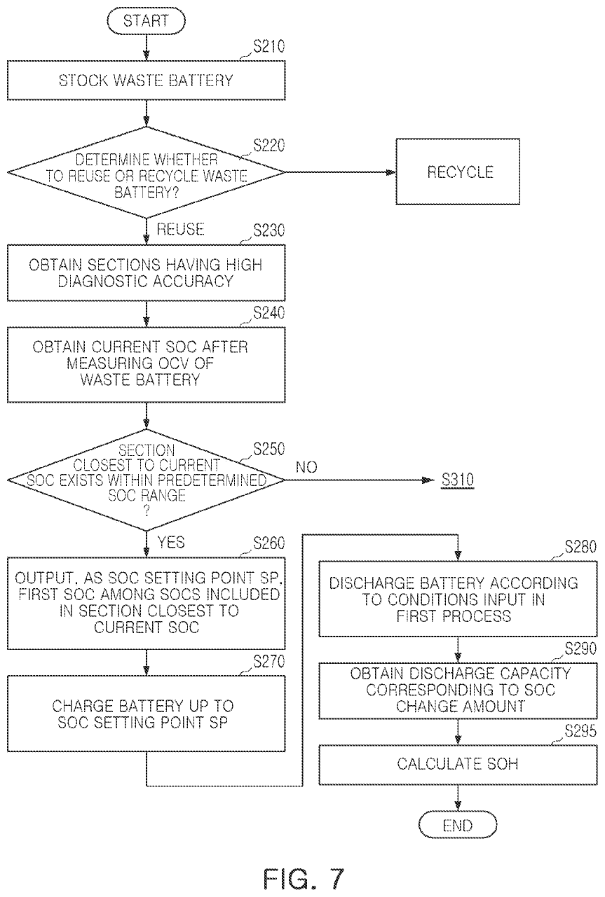

FIG. 6 is a schematic block diagram illustrating an apparatus for estimating a SOH of a battery according to an example embodiment of the present disclosure.

Referring to FIG. 6, an apparatus 200 for estimating a SOH of a battery, the apparatus 200 may include a memory 210, an SOC obtainer 220, an SOC setting point obtainer 230, and a SOH calculator 240. The memory 210 may store an SOC-OCV lookup table of a battery having a SOH of 100. In addition, sections having high diagnostic accuracy determined in a first process may be stored in the memory 210.

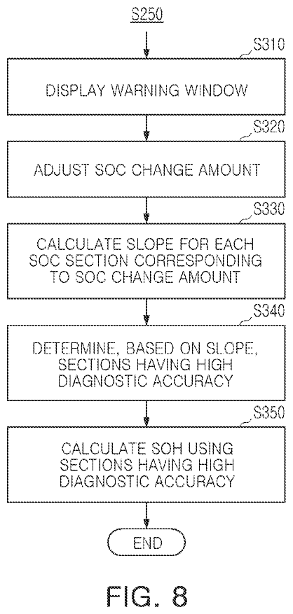

FIGS. 7 and 8 are flowcharts of a second process illustrating a method for estimating a SOH of a battery according to an example embodiment of the present disclosure.

Referring to FIGS. 6 and 7 together, a waste battery may be generated due to a case in which a battery of a vehicle has reached the end of a lifespan thereof or the vehicle is scrapped, and the waste battery may be stocked (S210).

When the waste battery is stocked, it may be determined whether to reuse or recycle the waste battery (S220). For example, an insulation state and appearance of the waste battery may be inspected, and when the waste battery has external dents or burn marks or there is a possibility that a short circuit may occur in the waste battery, the waste battery may not be reused and may be recycled (recycling in S220).

When it is determined that the waste battery is reusable (reuse in S220), the SOC obtainer 220 may read, from the memory 210, the SOC-OCV table of the SOH of 100. The SOC setting point obtainer 230 may read, from the memory 210, sections having high diagnostic accuracy confirmed through a first process (S230).

A voltage detector may be used to measure a current OCV of the waste battery. When the measured OCV is input to the apparatus 200, the SOC obtainer 220 may obtain a current SOC corresponding to the measured OCV from the SOC-OCV table of the battery having the SOH of 100 (S240).

The SOC setting point obtainer 230 may search for an SOC section closest to the current SOC within a predetermined SOC range among sections having high diagnostic accuracy.

When the SOC section closest to the current SOC exists within the predetermined SOC range (YES in S250), the SOC setting point obtainer 230 may output, as an SOC setting point SP, a first SOC among SOCs included in the SOC section closest to the current SOC (S260). For example, referring to FIG. 5, when the predetermined SOC range is 20(%) and the current SOC is 70(%), the SOC section closest to the current SOC within the predetermined SOC range may be a eighth SOC (SOC 8), and a first SOC included in the eighth SOC (SOC8) may be 80. The SOC setting point obtainer 230 may output 80 as the SOC setting point SP.

When the SOC setting point SP is obtained from the apparatus 200, the battery may be charged up to the SOC setting point SP using a charger/discharger (S260). For example, when the current SOC of the battery is 70 and the SOC setting point SP is 80, the SOC of the battery may be adjusted from 70 to 80 by charging the battery (S270).

After charging the battery up to the SOC setting point SP, the battery may be discharged according to conditions (for example, a diagnosis time and a current rate) input in the first process using the charger/discharger (S280). In other words, an SOC change amount (ΔSOC=10) may be calculated based on the diagnosis time and the current rate input in the first process, and thus the battery may be discharged to correspond to the SOC change amount (ΔSOC=10). For example, when the SOC setting point SP is 80 and the SOC change amount (ΔSOC) is 10, the battery may be discharged so that the SOC of the battery is from 80 to 70.

The charger/discharger may measure a discharge capacity corresponding to the SOC change amount (ΔSOC=10). The SOH calculator 240 may obtain the measured discharge capacity (S290).

The SOH calculator 240 may calculate a SOH based on an SOC change amount (ΔSOC), a BOL capacity, and a measured capacity (S295). The SOH may satisfy Equation 4.

$$SOH [ \% ] = \frac{measured capacity [ Ah ]}{Δ SOC X BOL capacity [ Ah ]} \times 100$$

Here, the BOL capacity may refer to an actual capacity of a battery right after shipment, that is, an earliest battery capacity, and the measured capacity may refer to a measured discharge capacity or a measured charge capacity.

For example, in case that a battery having a BOL capacity of 70 (Ab) is stocked as a waste battery after use for a predetermined period (for example, five years) and a SOH of at least one waste battery cell included in the waste battery is diagnosed, when an SOC change amount (ΔSOC) is 10(%) and a discharge capacity corresponding to the SOC change amount (ΔSOC=10) is 5.5 (Ah), the SOH may be as follows.

$$SOH = \frac{5.5 ( A h )}{10 ( \% ) ⨯ 70 ( Ah )} ⨯ 100 = 78.57 ( \% )$$

That is, the expected SOH of the battery used for five years may be 78.57(%).

Referring to FIGS. 6 and 8 together, when no SOC section closest to the current SOC exists within the predetermined SOC range (NO in S250), the apparatus 100 may display a warning window indicating that a diagnosis time input in a first process is not able to be met (S310), and may adjust an SOC change amount (ΔSOC) (S320).

For example, when an SOC change amount (ΔSOC) calculated based on a desired diagnosis time and current rate in the first process is 10, the slope calculator 130 may adjust the SOC change amount (ΔSOC) to correspond to a predetermined amount (for example, ±5). When the SOC change amount (ΔSOC) is changed, the diagnosis time may be changed. For example, when the SOC change amount (ΔSOC) is increased, the diagnosis time may be increased. Accordingly, the apparatus 100 may display a warning window indicating that the diagnosis time input in the first process is not able to be met.

The slope calculator 130 may calculate a slope S for each of SOC sections corresponding to SOC change amounts (ΔSOC=5, 15) adjusted in an SOC-OCV lookup table according to a SOH that a battery cell may have (S330). The slope calculator 130 may determine whether each of the SOC sections corresponding to the SOC change amounts (ΔSOC=5, 15) is a section in which a SOH is able to be diagnosed (S340).

The SOH may be calculated using sections having high diagnostic accuracy (S350). Specifically, an OCV of a waste battery may be measured using a voltage detector, and a current SOC corresponding to the measured OCV may be obtained. The SOC setting point obtainer 230 may search for an SOC section closest to the current SOC within a predetermined SOC range among the sections having high diagnostic accuracy.

For example, in case that no SOC section closest to the current SOC exists within the predetermined SOC range when the SOC change amount (ΔSOC) is 5, and an SOC section closest to the current SOC exists within the predetermined SOC range when the SOC change amount (ΔSOC) is 15, a first SOC among SOCs included in the SOC section closest to the current SOC when the SOC change amount (ΔSOC) is 15 may be output as an SOC setting point SIP.

In some example embodiments, in case that an SOC section closest to the current SOC exists within the predetermined SOC range when the SOC change amount (ΔSOC) is 5, an SOC section closest to the current SOC exists within the predetermined SOC range when the SOC change amount (ΔSOC) is 15, a slope deviation of the SOC section closest to the current SOC the when the SOC change amount (ΔSOC) is 15 is less than a slope deviation of the SOC section closest to the current SOC the when the SOC change amount (ΔSOC) is 5, a first SOC among SOCs included in the SOC section closest to the current SOC when the SOC change amount (ΔSOC) is 15 may be output as the SOC setting point SP.

When the SOC setting point SP is obtained from the apparatus 200, the battery may be charged up to the SOC setting point SP and be discharged to correspond to the SOC change amount (ΔSOC=15), using a charger/discharger, and a discharge capacity may be measured.

The SOH calculator 240 may calculate a SOH based on an SOC change amount (ΔSOC), BOL capacity, and measured capacity.

An example embodiment in which an SOC change amount (ΔSOC) is 10(%) is described herein, but the SOC change amount (ΔSOC) may be changed and applied in various manners, such as 15, 20, or the like.

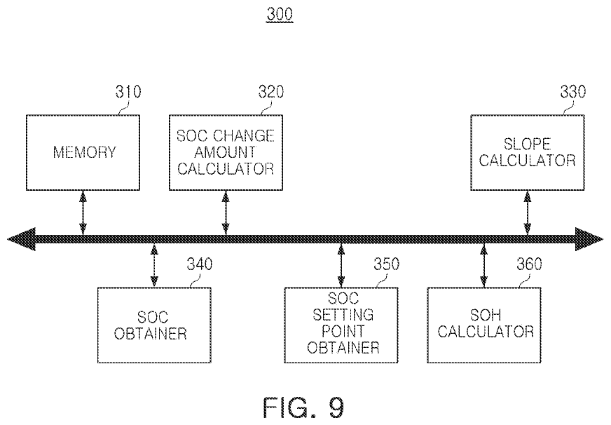

FIG. 9 is a schematic block diagram illustrating an apparatus for estimating a SOH of a battery according to an example embodiment of the present disclosure.

The apparatus 100 in FIG. 2 and the apparatus 200 in FIG. 6 may be one apparatus, and may be illustrated as an apparatus 300 for estimating a SOH of a battery in FIG. 9.

Referring to FIG. 9, the apparatus 300 may include a memory 310, an SOC change amount calculator 320, a slope calculator 330, an SOC obtainer 340, and an SOC setting point obtainer 350, and a SOH calculator 360.

The memory 310 may store an SOC-OCV lookup table according to a SOH that at least one battery cell may have.

The SOC change amount calculator 320 may calculate an SOC change amount (ΔSOC) corresponding to a diagnosis time (h) and a current rate (C-rate).

The slope calculator 330 may read, from the memory 310, the SOC-OCV lookup table according to the SOH that the battery cell may have, and may calculate a slope S for each SOC section corresponding to the SOC change amount (ΔSOC) in the SOC-OCV lookup table according to the SOH that the battery cell may have.

The slope calculator 330 may determine, based on the slope S, whether each SOC section corresponding to the SOC change amount ΔSOC is a section in which a SOH is able to be diagnosed. In other words, the slope calculator 330 may determine sections having high diagnostic accuracy among SOC sections corresponding to the SOC change amount (ΔSOC). The sections having high diagnostic accuracy may be stored in the memory 310.

The SOC obtainer 340 may read, from the memory 310, an SOC-OCV table of a SOH of 100. The SOC obtainer 340 may obtain, from the SOC-OCV table of the SOH of 100, a current SOC corresponding to an OCV of a waste battery.

The SOC setting point obtainer 350 may read, from the memory 310, the sections having high diagnostic accuracy. The SOC setting point obtainer 350 may search for an SOC section closest to the current SOC within a predetermined SOC range among the sections having high diagnostic accuracy.

When the SOC section closest to the current SOC exists within the predetermined SOC range, the SOC setting point obtainer 330 may output, as an SOC setting point SP, a first SOC among SOCs included in the SOC section closest to the current SOC.

When a discharge capacity is obtained by discharging the battery to correspond to the SOC change amount ΔSOC after charging the battery up to the SOC setting point SP, the SOH calculator 360 may calculate the SOH based on the SOC change amount ΔSOC, BOL capacity, and discharge capacity.

While example embodiments have been shown and described above, modifications and variations of the disclosed embodiments and other embodiments may be made based on what is disclosed in this patent document.

What is claimed is:

1. A method for estimating a state of health (SOH) of a battery, the method comprising:
a determining a state of charge (SOC)-open circuit voltage (OCV) lookup table according to an SOH of at least one battery cell;
determining a first SOC change amount based on a diagnosis time for diagnosing a current state of the battery and a current rate at which the battery is discharged, upon receipt of the diagnosis time and the current rate;
determining a first slope of SOC-OCV graph for each SOC section in the SOC-OCV lookup table corresponding to the first SOC change amount according to the SOH in the SOC-OCV lookup table; and
determining, based on the first slope, first SOC sections having a predetermined diagnostic accuracy in the SOC-OCV lookup table.

2. The method of claim 1, wherein the determining of the first slope for each SOC section comprises calculating an OCV change amount corresponding to the first SOC change amount, and calculating the first slope by dividing the OCV change amount by the first SOC change amount.

3. The method of claim 1, wherein the determining of the first sections having the predetermined diagnostic accuracy comprises determining, based on a deviation of the first slope for each of a plurality of SOH values in a same SOC section, whether a corresponding SOC section includes a diagnosable SOH.

4. The method of claim 1, further comprising:
obtaining a current SOC corresponding to an OCV of at least one waste battery cell included in a waste battery from an SOC-OCV lookup table of a battery having a SOH of 100; and
calculating a SOH of the at least one waste battery cell using the first sections having the predetermined diagnostic accuracy.

5. The method of claim 4, wherein the calculating of the SOH of the at least one waste battery cell comprises:
searching the SOC-OCV lookup table for a section closest to the current SOC within a predetermined SOC range among the first sections having the predetermined diagnostic accuracy;
outputting, as an SOC setting point, a first SOC among SOCs included in the section in a case that the section closest to the current SOC exists in the SOC-OCV lookup table;
obtaining a discharge capacity when the at least one waste battery cell is discharged up to the first SOC change amount after the at least one waste battery cell is charged up to the SOC setting point; and
calculating, based on the discharge capacity, the SOH of the at least one waste battery cell.

6. The method of claim 5, wherein the SOH of the at least one waste battery cell is expressed as:
$$SOH [ \% ] = \frac{Measured Capacity [ Ah ]}{Δ SOC ⨯ BOL capacity [ Ah ]} \times 100 ,$$
where ΔSOC refers to a first SOC change amount, the measured capacity refers to the discharge capacity, and a beginning of life (BOL) capacity refers to an initial capacity of the at least one waste battery cell.

7. The method of claim 5, further comprising:
calculating a second SOC change amount by adjusting the first SOC change amount in a case that no section closest to the current SOC exists in the SOC-OCV lookup table;
calculating a second slope for each SOC section corresponding to the second SOC change amount in the SOC-OCV lookup table according to the SOH; and
determining, based on the second slope, second sections having the predetermined diagnostic accuracy in the SOC-OCV lookup table.

8. The method of claim 7, further comprising:
calculating a third SOC change amount by adjusting the first SOC change amount;
calculating a third slope for each SOC section corresponding to the third SOC change amount in the SOC-OCV lookup table according to the SOH; and
determining, based on the third slope, third sections having the predetermined diagnostic accuracy in the SOC-OCV lookup table.

9. The method of claim 8, further comprising:
calculating the SOH of the at least one waste battery cell using the second sections having the predetermined diagnostic accuracy and the third sections having the predetermined diagnostic accuracy.

10. The method of claim 9, wherein the calculating of the SOH of the at least one waste battery cell comprises:
searching the SOC-OCV lookup table for a section closest to the current SOC within a predetermined SOC range among the second sections having the predetermined diagnostic accuracy;
searching the SOC-OCV lookup table for a section closest to the current SOC within a predetermined SOC range among the third sections having the predetermined diagnostic accuracy;
outputting, as an SOC setting point, a first SOC among SOCs included in the section closest to the current SOC among the second sections having the predetermined diagnostic accuracy in a case that the section closest to the current SOC exists among the second sections having the predetermined diagnostic accuracy and no section closest to the current SOC exists among the third sections having the predetermined diagnostic accuracy;
a obtaining a discharge capacity when the at least one waste battery cell is discharged up to the first SOC change amount after the at least one waste battery cell is charged up to the SOC setting point; and
calculating, based on the discharge capacity, the SON of the at least one waste battery cell.

11. The method of claim 9, wherein the calculating of the SOH of the at least one waste battery cell comprises:
searching the SOC-OCV lookup table for a section closest to the current SOC within a predetermined SOC range among the second sections having the predetermined diagnostic accuracy;
searching the SOC-OCV lookup table for a section closest to the current SOC within a predetermined SOC range among the third sections having the predetermined diagnostic accuracy;
outputting, as an SOC setting point, a first SOC among SOCs included in the section closest to the current SOC among the second sections having the predetermined diagnostic accuracy in a case that the section closest to the current SOC exists among the second sections having the predetermined diagnostic accuracy, the section closest to the current SOC exists among the third sections having the predetermined diagnostic accuracy, and a slope deviation of the section closest to the current SOC among the second sections having the predetermined diagnostic accuracy is less than a slope deviation of the section closest to the current SOC among the third sections having the predetermined diagnostic accuracy;
obtaining a discharge capacity when the at least one waste battery cell is discharged up to the first SOC change amount after the at least one waste battery cell is charged up to the SOC setting point; and
calculating, based on the discharge capacity, the SOH of the at least one waste battery cell.
